(19) United States
(12) Patent Application Publication
(10) Pub. No.: US 2022/0251712 A1
(43) Pub. Date: Aug. 11, 2022

(54) INSULATION LAYER FORMATION METHOD, MEMBER WITH INSULATION LAYER, RESISTANCE MEASUREMENT METHOD AND JUNCTION RECTIFIER

(71) Applicant: NEXT INNOVATION INC., Nishitokyo-shi Tokyo (JP)

(72) Inventor: Hiroshi Michiwaki, Nishitokyo-shi, Tokyo (JP)

(21) Appl. No.: 17/257,223

(22) PCT Filed: Jul. 11, 2019
(86) PCT No.: PCT/JP2019/027619

§ 371 Date: Apr. 27, 2021

(30) Foreign Application Priority Data
Jul. 11, 2018 (JP) 2018-131913

(51) Int. Cl. C23C 28/00; H01L 49/00; H05K 3/44; H05K 1/05; C25D 5/48; C25D 5/02; C23C 22/07; G01R 27/02; G01R 31/12

(52) U.S. Cl. CPC C23C 28/34; H01L 49/00; H05K 3/44; H05K 1/053; C23C 28/32; C25D 5/48; H05K 2203/1476; C23C 22/07; G01R 27/02; G01R 31/1227; H05K 2203/0776; H05K 2203/072; H05K 2203/0723; C25D 5/02

(57) ABSTRACT

An insulation layer formation method comprises: a first step in which a surface treatment is applied to a base material to form thereon a high-resistance layer having high electric resistivity; a second step in which metal plating parts are formed on the base material that has undergone the first step in such a manner as to allow a high-resistance layer to be formed thereon; and a third process in which a high-resistance layer is formed on the base material that has undergone the second step.

### CROSS-REFERENCE TO RELATED APPLICATIONS

This application is a national phase entry under 35 U.S.C. § 371 of International Patent Application PCT/JP2019/027619, filed Jul. 11, 2019, designating the United States of America and published as International Patent Publication WO 2020/013304 A1 on Jan. 16, 2020, which claims the benefit under Article 8 of the Patent Cooperation Treaty to Japanese Patent Application Serial No. 2018-131913, filed Jul. 11, 2018.

### TECHNICAL FIELD

The present disclosure relates to an insulation layer formation method, etc.

### BACKGROUND

In the related art, a multi-layered printed wiring board formed by alternately laminating conductor layers and insulation layers has been proposed (for example, refer to Patent Document 1). The insulation layer of the multi-layered printed wiring board is formed by overlapping a thermosetting resin layer and a liquid crystal polymer resin layer.

Further, a thin metal package in which an insulation layer is formed by directly changing a surface of a base metal, which configures a base member by a chemical reaction, and a pattern electrode is formed on the insulation layer (for example, refer to Patent Document 2). Here, the insulation layer is an anodized oxide film that is formed of an insulating metal compound, such as metal hydroxide or metal oxide, directly generated from a base metal and is installed by anodizing the base member.

### RELATED ART DOCUMENT

### Patent Document

[Patent Document 1] Japanese Laid-Open Patent Publication No. 2011-216841
[Patent Document 2] Japanese Laid-Open Patent Publication No. 2013-128037

### BRIEF SUMMARY

However, the insulation layer of the related art has several problems. For example, the insulation layer, which is formed of a resin layer, has a coefficient of thermal expansion different from that of the conductor layer so that there is a risk of defects such as peeling or cracking of the insulation layer with respect to the conductor layer. Further, when the insulation layer is resin, heat resistance or weather resistance is not sufficient so that deterioration is accelerated due to repeated thermal expansion, shrinkage, wetting, and drying due to environments of high temperature and high humidity. Therefore, there is a risk of defects such as peeling or cracking of the insulation layer with respect to the conductive layer.

Further, as disclosed in Patent Document 2, when a chemical reaction is applied to a surface of the base metal to form an insulation film, the defect such as peeling or cracking due to the difference in coefficients of thermal expansion or peeling or cracking due to the heat resistance or weather resistance may be suppressed to a certain degree. However, since the film thickness of the insulation film is not uniform, dielectric breakdown may easily occur in a portion with a small thickness. Further, in the insulation film, there is a plurality of so-called pin holes that become conduction portions, together with a portion with a small thickness. Even though very minute current flows through individual conduction portions, there is a plurality of conduction portions so that a total value of minute currents is the current that is applied to the insulation film as a whole. Therefore, when a conductive layer or a conductive pattern is formed on the insulation film having such a defect, the electrons move between the conductive layer and a conductive base material to apply electricity so that a normal circuit function cannot be achieved. Accordingly, there is a problem in that it is very difficult to employ it as an insulation film because it is dielectric but a comparatively high current is applied thereto.

An object of the present disclosure is to provide a means that has a simple and easy structure to prevent the peeling or cracking of the insulation layer and surely insulate.

### Technical Solution

According to an aspect of the present disclosure, there is provided an insulation layer formation method including: a first step in which a surface treatment is applied to a base material to form thereon a high-resistance layer having high electric resistivity; a second step in which metal plating parts are formed on the base material that has undergone the first step in such a manner as to allow a high-resistance layer to be formed thereon; and a third step in which a high-resistance layer is formed on the base material that has undergone the second step.

In the insulation layer formation method of the present disclosure, in the second step, the metal plating is formed in a minute conduction part of the high-resistance layer formed by the first step.

Further, in the insulation layer formation method of the present disclosure, the high-resistance layer is a phosphating layer formed by a phosphate chemical conversion treatment and the metal plating parts have metal to which a phosphate chemical conversion treatment is applicable and/or an oxidation treatment is applicable as a main component.

Further, in the insulation layer formation method of the present disclosure, the high-resistance layer of the third step is formed by the phosphate chemical conversion treatment and/or the oxidation treatment.

Further, the insulation layer formation method of the present disclosure is an insulation layer formation method that forms an insulation layer having a high electric insulating property on a base material on which a high-resistance layer is not able to be directly formed, including: a pre-process in which metal plating parts are formed on the base material as layers; a first step in which a surface treatment is applied to form a high-resistance layer having high electric resistivity on the metal plating parts; a second step in which metal plating parts are formed on the base material that has undergone the first step in such a manner as to allow a high-resistance layer to be formed thereon; and a third step in which a high-resistance layer is formed on the metal plating parts formed in the second step by applying a treatment for forming a high-resistance layer to the base material that has undergone the second step.

Further, in the insulation layer formation method of the present disclosure, the high-resistance layer is a phosphating layer formed by a phosphate chemical conversion treatment, and the metal plating parts have metal to which a phosphate chemical conversion treatment is applicable and/or an oxidation treatment is applicable as a main component.

Further, in the insulation layer formation method of the present disclosure, the high-resistance layer of the third step is formed by the phosphate chemical conversion treatment and/or the oxidation treatment.

Further, in the insulation layer formation method of the present disclosure, the second step and the third step are alternately repeated.

Further, in the insulation layer formation method of the present disclosure, in the second step, the metal plating parts are formed by wet plating.

Further, in the insulation layer formation method of the present disclosure, the metal plating parts have iron, tin, zinc, or nickel as a main component.

Further, the insulation layer formation method of the present disclosure includes a formation step in which a conductive layer is formed on an upper layer of the high-resistance layer that is an outermost surface.

Further, in the insulation layer formation method of the present disclosure, the conductive layer is formed with a planar shape, a linear shape, a mesh shape, a geometric shape and/or a dot shape, or a configuration configured by a combination thereof.

Further, in the insulation layer formation method of the present disclosure, the conductive layer forms a conductive pattern.

Further, in the insulation layer formation method of the present disclosure, a width, a thickness, and a direction installed on the high-resistance layer of the conductive layer are set so as to form an electric element.

According to another aspect of the present disclosure, a member with an insulation layer is formed such that a phosphating layer is formed on a surface of a base material, a conductive liquid is applied on a surface of the phosphating layer, an anode side probe is brought into contact with a conductive portion and a cathode side probe is brought into contact with the phosphating layer so that a resistance value measured by a planar type probe of approximately 78 mm² is 190 KΩ or higher.

Further, the member with an insulation layer of the present disclosure has an insulation layer configured by a substantially uniform phosphating layer on a surface of a base material.

Further, in the member with an insulation layer of the present disclosure, the insulation layer is a planar insulation layer in which everywhere of the entire surface where the insulation layer is formed is insulated.

Further, in the member with an insulation layer of the present disclosure, an insulation layer is mainly configured by a phosphating layer on a surface of a base material and metal oxides are scattered on the insulation layer.

Further, the member with an insulation layer of the present disclosure has a conductive layer on an upper layer of the insulation layer.

Further, in the member with an insulation layer of the present disclosure, the conductive layer forms a planar shape, a linear shape, a mesh shape, a geometric shape and/or a dot shape, or a configuration configured by a combination thereof.

Further, in the member with an insulation layer of the present disclosure, the conductive layer forms a conductive pattern.

Further, in the member with an insulation layer of the present disclosure, a width, a thickness, and a direction installed on the high-resistance layer of the conductive layer are set so as to form an electric element.

Further, in the member with an insulation layer of the present disclosure, the insulation layer has a withstanding voltage performance that exceeds a voltage applied to the conductive layer.

According to another aspect of the present disclosure, a resistance measurement method is a resistance measurement method for measuring a resistance value of a high-resistance layer formed on a member, in which the high-resistance layer is covered by a predetermined area or more and a resistance of the high-resistance layer is measured by a measurement device having a first contact that is in point contact with a plurality of portions of the high-resistance layer and/or is in planar contact with the high-resistance layer and a second contact that is in contact with a surface of the member other than the portions that are in contact with the first contact.

Further, in the resistance measurement method of the present disclosure, the member has a good conductivity and the second contact is in contact with a portion having a good conductivity of the member.

Further, in the resistance measurement method of the present disclosure, the member is covered by a high-resistance layer and the second contact is in contact with a surface covered by the high-resistance layer.

Further, in the resistance measurement method of the present disclosure, the first contact is a member that is in point contact with a plurality of portions of the high-resistance layer and/or in planar contact with the high-resistance layer, separately from the measurement device and a contact of the measurement device is in indirect contact with the high-resistance layer by means of the first contact.

Further, in the resistance measurement method of the present disclosure, a conductive fluid is disposed between the high-resistance layer and the first contact.

Further, according to another aspect of the present disclosure, a junction rectifier is a junction rectifier formed by junction of metal and phosphate, including: an anode side terminal that is directly or indirectly installed in the metal; and a cathode side terminal that is directly or indirectly installed in a phosphate.

Further, according to another aspect of the present disclosure, a junction rectifier is a junction rectifier formed by junction of metal and phosphate, including: a cathode side terminal that is directly or indirectly installed in the metal; and an anode side terminal that is directly or indirectly installed in a phosphate.

Further, in the junction rectifier of the present disclosure, the metal has iron in which a phosphate chemical conversion treatment is applicable as a main component.

Further, in the junction rectifier of the present disclosure, the phosphate is a phosphating layer.

According to the present disclosure, in accordance with a simple and easy formation method, a means that prevents the peeling or cracking of the insulation layer and surely insulates may be provided.

### BRIEF DESCRIPTION OF THE DRAWINGS

FIGS. 1A-1B illustrate a base material to which an insulation layer formation method related to the present example embodiment is applied.

FIG. 2 is a diagram illustrating a base material after a second step in an insulation layer formation method related to the present example embodiment.

FIGS. 3A-3B illustrate a base material after a third step in an insulation layer formation method related to the present example embodiment.

FIGS. 4A-4B illustrate a phosphating layer when an oxidation treatment is performed in the third step.

FIGS. 5A-5D illustrate a base material on which a metal plating part is formed in a pre-process.

FIG. 6 is a diagram illustrating a conduction part existing after a third step.

FIGS. 7A-7B illustrate formation of a phosphating layer when a second step and a third step are performed again.

FIG. 8 is a diagram illustrating an iron plating part formed by dry plating.

FIG. 9 is a diagram illustrating a phosphating layer formed on an iron plating part.

FIG. 10 is a diagram illustrating a conductive layer formed on an insulation layer.

FIGS. 11A-11B illustrate a measurement block.

### DETAILED DESCRIPTION

Hereinafter, in an insulation layer formation method according to the present disclosure, an insulation layer formation method by self-selective blockage treatment of a minute conduction part, which is an example of the embodiment, will be described. Further, in the present embodiment, even though as a target base material that forms the insulation layer, metal that is a good conductor will be described, the present embodiment is not limited thereto and a base material having electrical resistivity or a base material having an electrical insulating property may be appropriately set.

The insulation layer formation method of the present disclosure is a formation method of an insulation layer including a first step that forms a high-resistance layer on a base material by a surface treatment, a second step that forms a metal plating part on the base material that has undergone the first step in such a manner as to allow a high-resistance layer to be formed thereon, and then a process that forms a high-resistance layer. In the related art, even though the high-resistance layer is formed on the base material, so-called pin holes to which an electricity is applied or portions with a small thickness of the high-resistance layer, or a minute conductor in the high-resistance layer is continuously or intermittently present so that formation of a minute conduction part to which an electricity is applied when a voltage is applied cannot be avoided and the insulating property is not sufficient. In contrast, according to the present disclosure, the minute conduction part is filled with metal plating and a process of forming a high-resistance layer is further performed thereon to reduce the minute conduction part and achieve high insulating property.

A first step of the present disclosure is a process of forming a high-resistance layer on a base material. As the process of forming a high-resistance layer, there is a chemical conversion treatment or a phosphate chemical conversion treatment that forms a metal oxide layer on a surface of a base material using a rust promotor and/or a rust generator containing acid liquid such as hydrochloric acid or salt water.

The formation method of an insulation layer using a phosphate chemical conversion treatment is a method formed with at least first to third steps. That is, the method is formed with the first step in which a phosphate chemical conversion treatment is applied to the base material, the second step in which metal plating parts are self-selectively formed on the minute conduction part present in a phosphating layer formed by the first step to block the minute conduction part, and the third step in which the phosphate chemical conversion treatment is applied to the metal plating parts to insulate the metal plating parts. Further, in the second step, iron is precipitated with respect to a conductive portion (minute conduction part) that remains in the phosphating layer to be described below, and desirably, a treatment that precipitates iron is performed only in the conductive portion. By doing this, the iron plating parts are selectively formed only on the conductive portion in the phosphating layer, which is referred to as self-selective blockage of the minute conduction part by the iron plating parts.

Further, since the phosphate chemical conversion treatment is applied to the base material, the base material may be, for example, metal to which the phosphate chemical conversion treatment is applicable, such as iron or iron alloy, tin or tin alloy, zinc or zinc alloy, nickel or nickel alloy, aluminum or aluminum alloy.

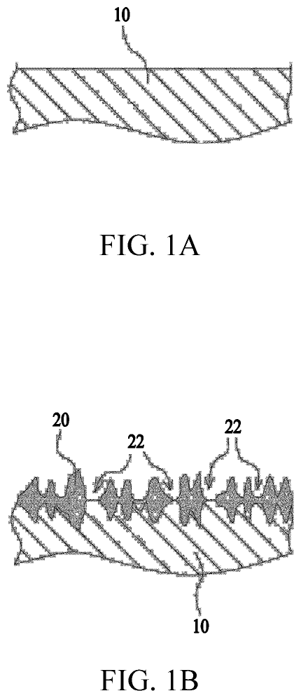

FIGS. 1A-1B illustrate a base material 10 to which an insulation layer formation method related to the present example embodiment is applied. FIG. 1A is a diagram illustrating a base material before the first step, and FIG. 1B is a diagram illustrating a base material after the first step. The first step is a process of applying a phosphate chemical conversion treatment to form a high-resistance layer (a layer having an insulating property) having a high electric resistivity with respect to the base material 10. As for the phosphate chemical conversion treatment for forming a layer having an insulating property, for example, a phosphate chemical conversion treatment solution that generates phosphates such as zinc phosphate, manganese phosphate, and zinc manganese phosphate on a surface of the base material is used.

Further, the first step may include a degreasing process, a water washing process, a water washing treatment process after the phosphate chemical conversion treatment process, a pure water washing process, and a drying process in addition to the phosphate chemical conversion treatment process, and in this step, a known method is applied.

Further, in the phosphate chemical conversion treatment process, a phosphate chemical conversion treatment solution is brought into contact with the surface of the base material by a spray method or a dipping method. By doing this, as illustrated in FIG. 1, a phosphating layer 20 is formed on the surface of the base material 10.

Further, as the phosphate chemical conversion treatment, for example, there is a method of dipping into the phosphate chemical conversion treatment solution and in this case, a liquid temperature may be desirably set to 95° C. or higher. Further, as another method, there is a method of applying a cathodic electrolytic treatment in the phosphate chemical conversion treatment solution. At this time, a current density is desirably 1 to 100 A/dm² and a temperature of liquid is 90° C. or lower. When the current density is lower than 1 A/dm², crystals (called phosphate crystals) that form an appropriate phosphating layer are not generated. Further, when the current density exceeds 100 A/dm², hydrogen gas is severely generated on the surface of the base material 10 during the cathodic electrolytic treatment so that it is difficult to grow the phosphating layer on the surface of the base material 10. In any case, the treatment time is desirably 5 to 60 minutes and more desirably 10 to 20 minutes.

The phosphate chemical conversion treatment solution has phosphate ions as an essential component and includes at least one metal ion selected from a group consisting of magnesium ions, aluminum ions, calcium ions, manganese ions, iron ions, cobalt ions, nickel ions, copper ions and zinc ions. Further, as the phosphate chemical conversion treatment solution, for example, phosphate ion may be desirably 3 to 50 g/L. When the phosphate ion is less than 3 g/L, a generation speed of the phosphating layer is delayed. Further, when the phosphate ion exceeds 50 g/L, a precipitating amount is increased due to a high concentration.

Further, nitrate ions are added to the phosphate chemical conversion treatment solution to improve stability of the phosphate chemical conversion treatment solution and polarization acceleration in cathodic electrolysis, or as a prooxidant, nitrite ions, hydrogen peroxide, and chlorite ions may be added. Further, as an electrode used for electrolytic treatment, carbon, stainless steel, platinum, titanium alloy, titanium-platinum coated alloy, or the like may be used.

Further, a surface control process may be performed before the phosphate chemical conversion treatment process and thus a surface of the base material is activated and a nucleus for precipitating a phosphate crystal may be created. A surface conditioner used for the surface control process may be appropriately selected depending on the phosphate and may be any one of liquid, a gelatinous material, and fluid. According to the surface control process, for example, a component that is a nucleus of the phosphate crystal is attached onto a surface of the base material 10. Accordingly, the phosphate crystal is generated to be grown from the component that serves as a nucleus. Further, the surface control process is performed so that the phosphate crystal becomes a dense crystal and a chemical conversion reaction may easily occur. Therefore, as compared with a case that the surface control process is not applied, a treatment time of the chemical conversion treatment process is shortened.

Similar to an insulation layer formed by applying a chemical reaction to the surface of the base metal as disclosed in Patent Document 2, on the phosphating layer 20 formed on the surface of the base material 10, there is a plurality of conductive portions 22 through which very minute current flows, such as portions with a small thickness that are minute conduction parts or pin holes. Such conductive portions 22 may be buried in the phosphating layer by the second step and the third step to be described below to be insulated.

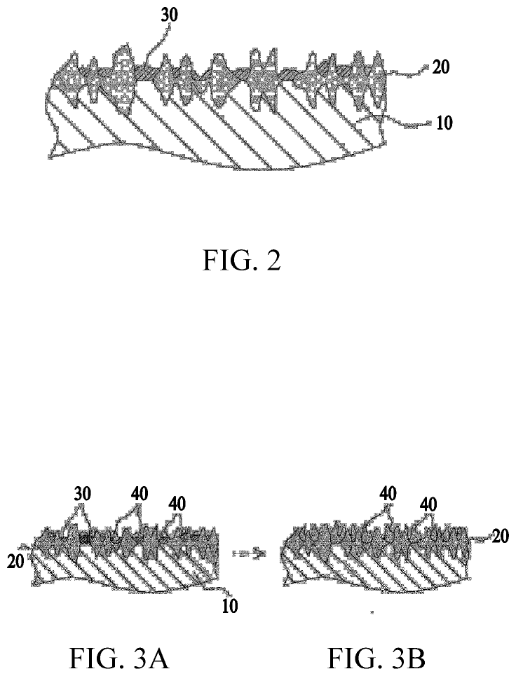

Next, the second step that is applied after the first step will be described. FIG. 2 is a diagram illustrating a base material 10 after a second step in an insulation layer formation method related to the present example embodiment. The second step is a process of forming an iron plating part as an upper layer of the phosphating layer 20. Hereinafter, even though it is described that the iron plating part is formed, the present disclosure is not limited thereto and any metal plating part that has a good adhesion to the phosphating layer, such as zinc plating part, tin plating part, and nickel plating part, and has a material to which the phosphate chemical conversion treatment is applicable in the third step to be described below as a main component.

Further, the iron plating part may be desirably plating with at least iron as a main component and for example, includes a pure iron plating part, an iron-carbon alloy plating part, an iron-based alloy plating part (Fe—W, Fe—Ni, Fe—P, Fe—Zn, Fe—Ni—Mo, Fe—Co, Fe—Cr, Fe—Cr—Ni), or the like.

The iron plating part may employ various plating methods, for example, dry plating such as physical vapor deposition (PVD) or chemical vapor deposition (CVD), hot dipping, or spraying, and desirably employ electrolytic plating or wet plating such as electroless plating to be described below.

The formation of the iron plating part by the electrolytic plating may be performed by a known method, and for example, use a sulfate bath or borofluoride bath. When the electrolytic plating is performed, an anode is dipped in the plating solution and at the same time, the base material 10 (cathode) is dipped so as to be opposite to the anode with an interval therebetween.

The anode is an iron metal plate. For example, two sheets of anodes are prepared and are dipped in the plating solution so as to be opposite to each other with an interval therebetween. In that case, the base material 10 is disposed between two sheets of anodes and is dipped in the plating solution to be opposite to each anode with an interval from each anode.

When the sulfate bath is used, the temperature of the plating solution is desirably in the range of 20° C. to 38° C. Electroplating is performed with a constant current to form an iron plating part while maintaining the temperature of the plating solution within a predetermined range. When the sulfate bath is used, the current density may be 2.5 to 10 A/dm².

Iron is precipitated on the conductive portion 22 in the phosphating layer 20 as illustrated in FIG. 2 by performing the electroplating according to the above-described method to form an iron plating part 30. That is, the plating is formed on an electrifying portion, according to the electroplating, so that the iron plating part 30 is formed with respect to a conductive portion 22 through which current flows such as a minute conduction part (for example, pin holes or portions that have a small thickness or easily cause dielectric breakdown) in the phosphating layer 20 having an insulating property.

Next, the third step will be described. FIGS. 3A-3B illustrate a base material 10 after a third step in an insulation layer formation method related to the present example embodiment. The third step is a process of forming a second phosphating layer 40 on the iron plating part 30.

Here, the second phosphating layer 40 may be formed by applying the same phosphate chemical conversion treatment as in the first step. The second phosphating layer 40 is formed as an upper layer of the iron plating part 30. That is, the phosphate chemical conversion treatment is hardly effective on the phosphating layer 20 that has been already formed so that the phosphate crystal is hardly precipitated. In contrast, the phosphate chemical conversion treatment is effective on the iron plating part 30 and as illustrated in FIG. 3A, in a portion where the iron plating part 30 is formed, the phosphate crystal is precipitated on the surface thereof. Further, as the phosphate chemical conversion treatment is proceeded, as illustrated in FIG. 3B, the second phosphating layer 40 is formed so as to cover the portions where the iron plating parts 30 are formed.

Accordingly, in a portion where the iron plating part 30 is formed in a portion that was the conductive portion 22 of the phosphating layer 20 formed in the first step, the phosphate crystal is precipitated, to form a second phosphating layer 40 so as to voluntarily and selectively bury a portion that was the conductive portion 22 of the phosphating layer 20 formed in the first step. By doing this, the conductive portion 22 of the phosphating layer 20 is filled with the second phosphating layer 40 so that an entire surface of the base material 10 may be covered with an insulation layer configured by substantially uniform phosphating layer in which the conductive portion 22 barely exists.

Further, since the conductive portion 22 barely exists, the insulation layer of the present disclosure is a planar insulation layer in which everywhere in the phosphating layer is insulated.

Further, the second phosphating layer 40 does not necessarily use the same phosphate chemical conversion treatment as in the first step, but may use any other phosphate chemical conversion treatment. For example, as the phosphate chemical conversion treatment in the first step, a treatment for forming a manganese phosphate layer is applied and as the phosphate chemical conversion treatment in the third step, a treatment for forming a zinc manganese phosphate layer may be applied.

As described above, according to the insulation layer formation method according to the present example embodiment, the surface treatments are performed in the order of the phosphate chemical conversion treatment on the base material, the treatment for forming an iron plating part by electroplating, and the phosphate chemical conversion treatment to bury (fill) pin holes or conductive portions with a small thickness generated on the initially formed phosphating layer with the phosphating layer. Accordingly, the insulation layer having a significantly high insulating property is formed to highly insulate the surface of the base material. Further, since the insulation layer is not formed of resin, peeling or cracking of the insulation layer due to the difference in coefficients of thermal expansion of the base material and the insulation layer is prevented to suppress the lowering of strength due to deterioration under an environment of high temperature or high humidity.

Further, in the second step, the iron plating part may be formed by electroless plating. In this case, as the plating solution, a self-catalytic (reduction type) plating solution for electroless plating is employed and a temperature of the plating solution is 70° C. to 100° C., and desirably 85° C. to 95° C. By doing this, the iron plating part is formed in a conductive portion formed of pin holes and when the third step is further applied, the conductive portion formed of the pin holes is filled by the phosphating layer so that the surface of the base material may be covered by the phosphating layer as an insulation layer.

Further, the thickness of the iron plating may be set to be equal to or lower than a thickness limit that may form the phosphating layer to be formed in the third step. This is because when the thickness of the iron plating is too thick, iron molecules of the iron plating beyond the thickness of the layer that forms the phosphating layer in the third step remain without being phosphated so that the remaining iron molecules may form the minute conduction part.

The thickness of the iron plating may be formed by controlling time. Further, the time for iron plating may be 1 minute to 60 minutes, and desirably, 2 minutes to 10 minutes. However, the time for iron plating may be changed to an appropriate treatment time by a size or the number of minute conduction parts generated in the phosphating layer generated in the first step.

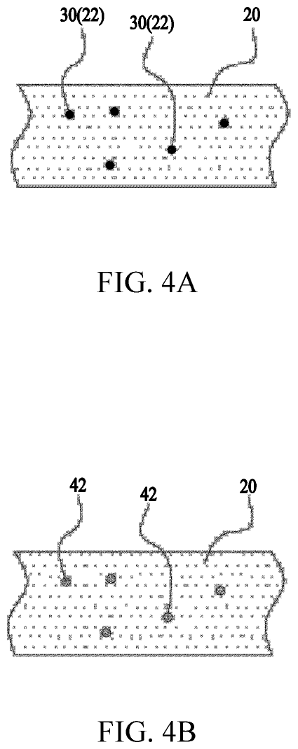

Even though in the above-described example embodiment, it has been described that the phosphate chemical conversion treatment is applied in the first step and the third step, if an oxidation treatment can form a high-resistance layer, the oxidation treatment may be used. That is, in the first step, the phosphate chemical conversion treatment is applied and in the third step, the oxidation treatment is applied. Here, FIGS. 4A-4B illustrate a phosphating layer when the oxidation treatment is applied in the third step and as illustrated in FIG. 4A, when portions where the iron plating part 30 is formed are scattered as conductive portions 22 in the phosphating layer 20, the oxidation treatment is applied to oxidize the iron plating part 30. By doing this, as illustrated in FIG. 4B, the iron plating part becomes a metal oxide 42 corresponding to a high-resistance layer such as the phosphating layer. Accordingly, the surface of the iron plating part formed in the second step is oxidized to be a metal oxide 42 so that the conductive portion 22 may be insulated.

Further, in the third step, after applying the phosphate chemical conversion treatment, the oxidation treatment may be further applied. Further, as a method for the oxidation treatment, various methods such as applying an anodized oxidation layer formation treatment to the base material 10, heating the base material 10 under a high concentration of oxygen, or dipping in an oxidation (acceleration) treatment solution may be appropriately selected.

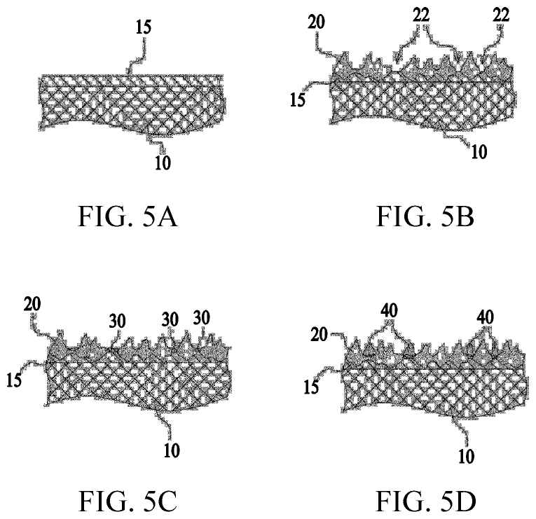

Further, since the phosphate chemical conversion treatment is applied in the first step and the third step, it has been described that the base material is metal to which the phosphate chemical conversion treatment is applicable. However, when the base material is metal to which it is difficult to apply the phosphate chemical conversion treatment (for example, copper or some of stainless steels), as a pre-process before the first step, as illustrated in FIG. 5A, a treatment for forming a metal plating part 15 on which the phosphate chemical conversion treatment is available may be applied to the base material 10. As described above, when the first step is applied, as illustrated in FIG. 5B, the phosphating layer 20 may be formed on the metal plating part 15. Next, when the second step is applied, as illustrated in FIG. 5C, the iron plating part 30 may be formed on the phosphating layer 20. Next, when the third step is applied, as illustrated in FIG. 5D, the second phosphating layer 40 may be formed as an upper layer of the iron plating part 30. As a result, even though it is difficult to apply the phosphate chemical conversion treatment on the base material 10, if the metal plating part 15 is directly formed on the base material 10, the insulation layer may be formed by the above-described first to third steps. The base material is not limited to metals, but may use resin, ceramics, or glass and in this case, by conductive surface modification or treatment, plating, or the like, a layer on which the phosphate chemical conversion treatment is applicable is formed in advance on the surface of the base material.

Accordingly, the formation method of an insulation layer according to the present disclosure may be applied to a base material on which it is difficult to apply the phosphate chemical conversion treatment. Further, as the metal plating part that is applied to the pre-process, for example, an iron plating part, a tin plating part, a zinc plating part may be appropriately set.

Further, as the plating method in the pre-process, it is not specifically limited, but may be appropriately selected from dry plating, wet plating, hot dipping plating, and the like. However, like physical vapor deposition, chemical vapor deposition, or electroless plating method using ion liquid, a method of forming the metal plating part on the entire base material may be desirably used.

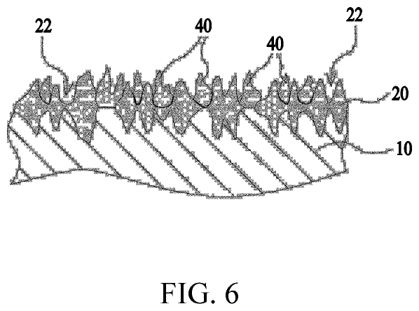

Further, in the above-described example embodiment, after the third step, the second step and the third step may be repeated again. By doing this, as illustrated in FIG. 6, when there is still a conductive portion 22 even after the third step, the second step is applied again to form the metal plating part in the conductive portion 22. Here, the metal plating part may be an iron plating part as in the second step initially applied. However, any other metal plating part such as a tin plating part, a zinc plating part, or a nickel plating part may be used.

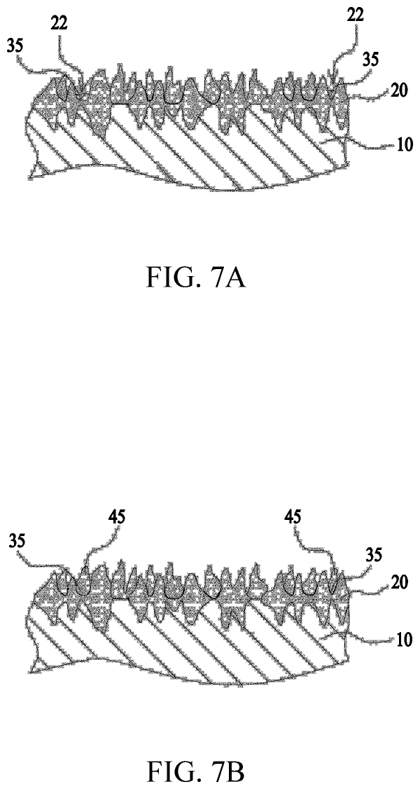

That is, when the second step is applied again after the third step, as illustrated in FIG. 7A, an iron plating part 35 is formed for the remaining conductive portion. When the third step is applied again, as illustrated in FIG. 7B, the iron plating part 35 is dissolved to form a phosphating layer 45. As a result, the phosphating layer 45 is formed in the conductive portion 22 so that an insulation layer having a higher insulating property may be formed. Even though the number of times of repeating the second step and the third step is not specifically limited, the number of repeating times is increased to reduce the conductive portion 22 or increase the thickness of the layer formed on the base material.

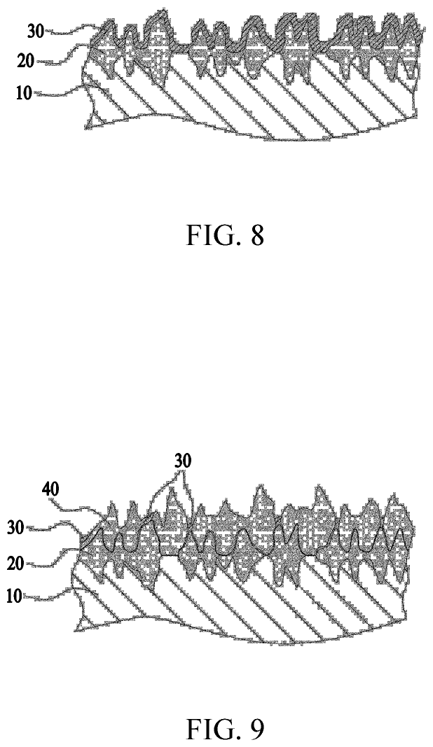

Needless to say, the iron plating part of the second step may be formed by dry plating. In this case, the iron plating part may be formed over the entire base material to cover most of the entire area of the phosphating layer including the conductive portion 22 as illustrated in FIG. 8.

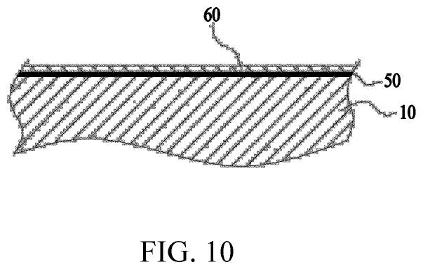

Next, when the third step is applied, as illustrated in FIG. 9, the surface of the iron plating part is dissolved and the phosphate crystal is precipitated to form the phosphating layer. At this time, the iron plating part is not completely dissolved, but may remain on the phosphating layer where the iron plating part is originally fixed or a new phosphating layer is formed as an upper layer thereof. That is, the phosphating layer may be laminated with the iron plating part locally interposed.

Further, even though the minute conduction part may be generated even on the phosphating layer formed by the third step, the minute conduction part is unlikely to communicate with the minute conduction part of the phosphating layer by the first step. It depends on that when the thickness of the iron plating part is set to be equal to or less than an upper limit of the thickness of the phosphating layer to be formed by the phosphate chemical conversion treatment that is applied as a subsequent treatment, most of iron components generated on the phosphating layer that is formed in advance by the iron plating is substituted into the phosphating layer so that most of the iron components that are conductive components may be lost. That is, the possibility of generating a minute conduction part that may communicate with the base material may be significantly reduced by laminating the phosphating layer by intervening the iron plating through a plurality of steps.

Further, in the above-described wet plating, when the dipping time of the base material in the plating solution is set to be long, the iron plating part formed with respect to the conductive portion may cover the entire phosphating layer and as a result, similar to the dry plating, the iron plating part may be formed over the entire base material to cover substantially the entire area of the phosphating layer including the conductive portion 22.

As described above, when the phosphating layer formed over the entire base material is laminated, the thickness of the laminated phosphating layer is increased to remove the conductive portion caused by the small thickness and also remove a conductive portion caused by the pin holes. Therefore, an insulation layer having a high insulating property that has not only a high electric resistance, but also a high withstanding voltage may be formed. Further, the peeling or cracking of the insulation layer due to the difference in coefficients of thermal expansion of the base material and the insulation layer is prevented to suppress the deterioration under the environment of high temperature or high humidity.

Further, the formation of the insulation layer is achieved by the completion of the third step as described above, but a conductive layer, a conductive pattern, or an electric element may also be formed by the subsequent treatment. For example, a conductive layer 60 having conductivity may be disposed on the insulation layer 50 (an insulation layer including the phosphating layer 20 and the second phosphating layer 40) illustrated in FIG. 10. Such a conductive layer 60 may be directly formed on the insulation layer 50, for example, by laminated printing, pad printing, painting, plating, inkjet printing, sputtering, spray coating, hot dipping, thermal spraying, etc. using a conductive paste.

Further, the conductive layer 60 may be formed with various shapes such as a planar shape, a linear shape, a mesh shape, a geometric shape, a dot shape, or a configuration formed by a combination thereof. Therefore, the conductive layer may be formed with a linear shape to form a conductive pattern. Further, the conductive pattern may be formed by a patterning process after forming a planar shape. In this case, the patterning process may be, for example, etching, cutting, laser processing, and a masking method and may be any one that removes unnecessary parts.

Further, together with the formation of the conductive layer, the electric elements may be formed. For example, the conductive layer is formed with a linear shape and spirally installed along an outer peripheral surface of the base material to form a coil, or a line width or a line thickness of the linear type conductive layer is formed to be small to form a resistance portion having a high electric resistance. Further, an insulation layer is provided between the base material and the conductive layer so that a capacitor may be formed. Needless to say, the insulation layer and the conductive layer are further alternately formed on the conductive layer to form a capacitor.

Further, a protection layer may be formed on the conductive layer and for example, a material of the protection layer may include ionizing radiation curable resins that are cured by light or electron beams, thermosetting resins that are heated to be cured, and photosensitive resins that are cured by ultraviolet rays, and a resin layer may be formed as a protection layer by a method such as a painting, dipping, or spraying method.

Further, target members on which an insulation layer is formed are buildings such as residential houses, multiple dwelling houses, or buildings, structures or constructions (hereinafter, the structures and constructions are collectively referred to as a construction) such as bridges, steel towers, railways, pipelines, plants, power plants, wind power generators, or solar power generators, various members such as building materials and structural materials used for them, industrial machines such as construction machines and machine tools, and other mechanical devices, consumables that configure the mechanical devices, such as fastening members, gears, blades of knives, or holding members, element parts such as springs, bearings, or linear guides, various transportation means such as rockets, aircrafts, submarines, ships, subways, buses, trucks, passenger cars, motorcycles, bicycles, or elevators, office and household equipment, and members used in various situations such as daily necessities.

Further, the insulation layer in each above-described example embodiment may be installed on the entire surface of the member or may be installed in a part of the surface of the member. For example, when the above-described patterning is applied, the insulation layer may be formed in a portion to be patterned or around the portion to be patterned, and a range for forming the insulation layer may be appropriately set.

### Examples

Hereinafter, the present disclosure will be described in more detail with reference to Examples. However, each of the Examples is not intended to limit the present disclosure.

In the Examples and the Comparative Examples, a processing order of the first step to the third step, measurement of the insulating property, measurement of a withstanding voltage, and evaluation of a rust preventive property are performed as follows.

[Base Material]

A SPCC plate with a thickness of 0.475 mm, a width of 30 mm, and a length of 100 mm was used as a base material for forming an insulation layer.

[First Step]

On the SPCC plate, as a phosphating layer, any one layer of a manganese phosphate layer, a zinc manganese phosphate layer, and a zinc phosphate layer was formed. Here, when the manganese phosphate layer was formed, the SPCC plate was dipped in a manganese phosphate treatment solution for 11 minutes at 95° C. As the manganese phosphate treatment solution, a solution (a bath agent manufactured by Chemicoat Co., Ltd, and having a brand name of Chemicoat No. 618) containing phosphoric acid, a manganese compound, and a nickel compound was used. After dipping in the manganese phosphate treatment solution, the SPCC plate was washed with water.

[Second Step]

First, the SPCC plate was dipped in an electroless iron plating solution for 4 minutes at 90° C. Here, the electroless iron plating solution contained ferrous sulfate (heptahydrate) of 158.66 g/L, sodium hypophosphate of 120 g/L, sodium citrate of 60 g/L, and sodium acetate of 60 g/L, respectively.

[Third Step]

In the third step, the same treatment as the dipping into the manganese phosphate treatment solution in the first step was applied. That is, the SPCC plate was dipped in the same treatment solution as the manganese phosphate treatment solution in the first step for 11 minutes at 95° C. After dipping in the manganese phosphate treatment solution, the SPCC plate was washed with water.

[Measurement of Insulating Property]

[Needle Contact]

In order to confirm the insulating property of the surface of the SPCC plate, a resistance value was measured. Specifically, a resistance value of the manganese phosphate layer was measured by a digital multi tester (TDB-401) (simply referred to as a tester) of OHM ELECTRIC INC. Further, when the resistance value was measured, a position of a probe (contact) was changed. That is, an anode side probe was located to the manganese phosphate layer and a cathode side probe was located as a line terminal of a conductive portion of a good conductor of the SPCC plate to measure the resistance values.

[Planar Contact]

Further, measurement by a planar contact that was different from needle contact was performed. Here, the planar contact refers to making a contact of a metal surface (a planar type contact) with the manganese phosphate layer. The measurement by a planar contact is measurement in a state in which an anode side probe of the tester is in indirect contact with the manganese phosphate layer to be conducted through the metal surface.

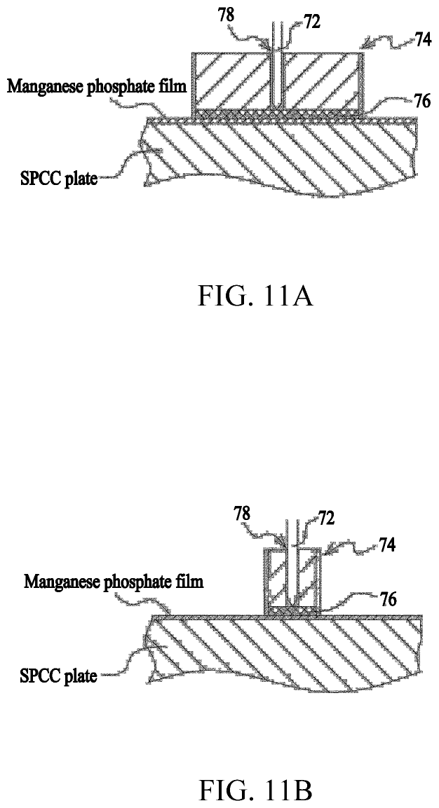

Therefore, the anode side probe was inserted into a measurement block 74 (see FIGS. 11A-11B) as a planar type contact to mount the measurement block 74. Further, a leading end of the cathode side probe was in contact with a conductive portion of the SPCC plate having a good conductivity other than the manganese phosphate layer. Further, the planar type contact forms a block shape and is a separate measurement block 74 from the probe, but is not necessarily separated, and the probe itself may serve as a planar type contact.

The measurement block 74 has a bottom 76 that forms a metal surface as illustrated in FIG. 11A. The bottom 76 is in planar contact with the manganese phosphate layer and the probe 72 is inserted into a hole 78 of the measurement block 74 such that a leading end is in contact with the bottom 76. Therefore, the probe 72 is in indirect contact with the manganese phosphate layer by means of the bottom 76. Further, in the measurement block 74, the hole 78 is not necessarily provided, but the measurement block 74 is integrally formed with the probe 72 to allow the probe 72 to make planar contact. Further, the bottom 76 of the measurement block 74 had a circular shape with a diameter of 10 mm and an area of approximately 78 mm².

Further, generally, even though the resistance value was measured by needle contact, when checked using a commercial measurement probe, it was discovered that different resistance values were measured depending on contact portions of the probe. That is, when the probe was in contact with a conductive portion of the manganese phosphate layer, the resistance value was measured to be low, but when the probe was in contact with a portion avoiding the conductive portion, the resistance value was measured to be high. By the way, in order to more objectively check whether it is insulated more than a normal method, in the present example embodiment, the measurement by the planar contact was performed.

Even though another probe was in direct contact with the SPCC plate, needless to say, the probe may be conducted with the SPCC plate by means of the measurement block 74. Further, it was described that the bottom 76 of the measurement block 74 was in planar contact with the manganese phosphate layer, but the present disclosure is not limited thereto.

For example, the bottom 76 may cover a predetermined area or more of the manganese phosphate layer and may be in point contact with a plurality of portions of the manganese phosphate layer. That is, the bottom 76 may have a plurality of protrusions on a surface facing the manganese phosphate layer to be in contact with the manganese phosphate layer. Further, needless to say, the bottom 76 may have both a portion that is in planar contact with the manganese phosphate layer and protrusions that are in point contact therewith.

[Water+Planar Contact]

A surface of a general manganese phosphate layer had a thickness that was not uniform and included a plurality of minute conduction parts so that in addition to the above-described measurement of the resistance value, water that was conductive fluid having a conductivity was applied between the measurement block 74 and the manganese phosphate layer to measure the resistance value while burying the conductive portion with the fluid.

[Withstanding Voltage Test]

As a withstanding voltage tester, a digital insulation resistance tester (MY600 manufactured by Yokogawa Electric Corp) was used and an electrode was abutted on the SPCC plate to apply a voltage and a resistance value was measured by gradually raising an applied voltage in the order of 5 V, 50 V, 125 V, 250 V, 500 V, and 1000 V.

Further, an effective maximum display value of a resistance value of the withstanding voltage tester was 100 MΩ at an applied voltage of 50 V, 250 MΩ at an applied voltage of 125 V, 500 MΩ at an applied voltage of 250 V, 2000 MΩ at an applied voltage of 500 V, and 4000 MΩ at an applied voltage of 1000 V.

An applied voltage when a resistance value that was equal to or lower than a predetermined value was measured, was a dielectric breakdown voltage (an upper limit of a withstanding voltage). Further, also in the withstanding voltage test, both measurement methods of needle contact and planar contact were applied as described above. Further, a measurement by switching the positions of the anode side probe and the cathode side probe was performed.

[Evaluation of Rust Preventive Property]

In order to check the rust preventive property, a salt water dipping experiment for dipping into 5 wt % of NaCl solution was performed. In the salt water dipping experiment, a dipping time when rust was generated on the SPCC plate after dipping into the salt water was measured.

### Comparative Examples 1 and 2 and Examples 1 to 9

An SPCC plate having the number of manganese phosphate layers as indicated in Tables 1 and 2 was obtained by the treatment by the first step to third step as described above. In an SPCC plate of Comparative Example 1, the treatment by the first step to third step was not applied and there was no a manganese phosphate layer. With respect to an SPCC plate of Comparative Example 2, the treatment by only the first step was applied and one manganese phosphate layer was used.

With respect to an SPCC plate of Examples 1 to 9, the treatment by the first step to third step was applied and 2 to 10 manganese phosphate layers were used.

TABLE 1

| | | Tester [Ω] | | | | | |
|---|---|---|---|---|---|---|---|
| | Number | Needle contact | | Planar contact | | Water + planar contact | |
| | of | Conductive | Conductive | Conductive | Conductive | Conductive | Conductive |
| | layers | portion (+) | portion (−) | portion (+) | portion (−) | portion (+) | portion (−) |
| Comp. | 0 | 0.000 | 0.000 | | | | |
| Ex. 1 | | | | | | | |
| Comp. | 1 | OL | OL | Several KΩ | Several KΩ | Several KΩ | Several |
| Ex. 2 | | | | to several | to several | to several | hundreds of |
| | | | | MΩ | MΩ | hundreds of | KΩ to several |
| | | | | | | KΩ | MΩ |
| Ex. 1 | 2 | OL | OL | OL | OL | 360K | 12M |
| Ex. 2 | 3 | OL | OL | OL | OL | 300K | 18M |
| Ex. 3 | 4 | OL | OL | OL | OL | 200K | OL |
| Ex. 4 | 5 | OL | OL | OL | OL | 190K | 1M |
| Ex. 5 | 6 | OL | OL | OL | OL | 400K | OL |
| Ex. 6 | 7 | OL | OL | OL | OL | 660K | OL |
| Ex. 7 | 8 | OL | OL | OL | OL | 400K | OL |
| Ex. 8 | 9 | OL | OL | OL | OL | 400K | OL |
| Ex. 9 | 10 | OL | OL | OL | OL | 1.4M | OL |

OL: 40 MΩ or higher

TABLE 2

| | | Withstanding voltage tester [V, Ω] | | | | | | | | |
|---|---|---|---|---|---|---|---|---|---|---|
| | | Needle contact | | | | Planar contact | | | | |
| | | Conductive portion (+) | | Conductive portion (−) | | Conductive portion (+) | | Conductive portion (−) | | |
| | | Applied | | Applied | | Applied | | Applied | | Rust |
| | Number | voltage | Resistance | voltage | Resistance | voltage | Resistance | voltage | Resistance | preventive |
| | of layers | [V] | value [Ω] | [V] | value [Ω] | [V] | value [Ω] | [V] | value [Ω] | property |
| Comp. | 0 | | | | | | | | | |
| Ex. 1 | | | | | | | | | | |
| Comp. | 1 | 50 | Dielectric | 125 | Dielectric | 50 | Dielectric | 125 | Dielectric | Rust was |
| Ex. 2 | | | breakdown | | breakdown | | breakdown | | breakdown | generated in |
| | | | | | | | | | | large area for |
| | | | | | | | | | | approximately |
| | | | | | | | | | | six hours |
| Ex. 1 | 2 | 500 | Dielectric | 500 | Dielectric | 500 | Dielectric | 500 | Dielectric | Salt water was |
| | | | breakdown | | breakdown | | breakdown | | breakdown | discolored |
| | | | | | | | | | | into reddish |
| | | | | | | | | | | brown by rust |
| | | | | | | | | | | after 48 hours |
| Ex. 2 | 3 | 500 | Dielectric | 500 | Dielectric | 500 | Dielectric | 500 | Dielectric | |
| | | | breakdown | | breakdown | | breakdown | | breakdown | |
| Ex. 3 | 4 | 500 | Dielectric | 500 | Dielectric | 500 | Dielectric | 500 | Dielectric | |
| | | | breakdown | | breakdown | | breakdown | | breakdown | |
| Ex. 4 | 5 | 500 | Dielectric | 500 | 1500M | 500 | Dielectric | 250 | 170M | Rust was |
| | | | breakdown | | | | breakdown | | | generated only |
| | | | | | | | | | | in portion with |
| | | | | | | | | | | surface defect |
| | | | | | | | | | | after six hours |
| | | | | | | | | | | thirty minutes |
| | | | | | | | | | | Rust was |
| | | | | | | | | | | entirely spread |
| | | | | | | | | | | with respect to |
| | | | | | | | | | | portion with |
| | | | | | | | | | | defect after 48 |
| | | | | | | | | | | hours |
| Ex. 5 | 6 | 1000 | Dielectric | 1000 | Dielectric | 500 | Dielectric | 500 | Dielectric | |
| | | | breakdown | | breakdown | | breakdown | | breakdown | |
| Ex. 6 | 7 | 1000 | Dielectric | 1000 | Dielectric | 500 | Dielectric | 500 | Dielectric | |
| | | | breakdown | | breakdown | | breakdown | | breakdown | |
| Ex. 7 | 8 | 1000 | Dielectric | 1000 | Dielectric | 500 | Dielectric | 500 | Dielectric | |
| | | | breakdown | | breakdown | | breakdown | | breakdown | |
| Ex. 8 | 9 | 500 | 1000M | 1000 | Dielectric | 500 | Dielectric | 500 | Dielectric | |
| | | | | | breakdown | | breakdown | | breakdown | |
| Ex. 9 | 10 | 1000 | Dielectric | 1000 | Dielectric | 500 | 70M | 500 | Dielectric | Rust was not |
| | | | breakdown | | breakdown | | | | breakdown | generated for |
| | | | | | | | | | | 240 hours or |
| | | | | | | | | | | longer |

In Tables 1 and 2, the conductive portion (+) represents a measurement result when an anode side probe is in contact with the conductive portion (a surface of a base material of the SPCC plate) and a cathode side probe is in contact with a manganese phosphate layer. The conductive portion (−) represents a measurement result when the anode side probe is in contact with the manganese phosphate layer and the cathode side probe is in contact with a conductive portion.

Results from Comparative Examples and Examples were as represented in Tables 1 and 2. Thicknesses of the SPCC plates of Comparative Example 2 and Examples 1 to 9 were substantially constant regardless of the number of manganese phosphate layers. In Table 1, the measurement result of the tester is represented as OL because the result exceeds 40 MQ, which is a resistance value measurable by the tester. Further, in Table 2, when the resistance value is represented as dielectric breakdown, it represents that when a corresponding applied voltage is applied, dielectric breakdown occurs. Accordingly, the dielectric breakdown voltage does not necessarily correspond to the applied voltage.

Specifically, in the result represented in the conductive portion (+) of the needle contact of Example 1 in Table 2, the dielectric breakdown occurs at an applied voltage of 500 V. This is because when the applied voltage is 250 V, the resistance value exceeds 50 MΩ so that the resistance value cannot be measured. Therefore, when the applied voltage is set to 500 V, the dielectric breakdown occurs. In this case, the resistance value was recorded as dielectric breakdown and the applied voltage was recorded as 500 V. Accordingly, an actual dielectric breakdown voltage is considered as an applied voltage in the range of more than 250 V and 500 V or less.

It is understood that as compared with Comparative Examples 1 and 2, in Examples 1 to 9, a resistance value by the tester is higher and the insulating property is greatly improved. This is because the iron plating part is formed in a conductive portion of the manganese phosphate layer formed by the first step and a manganese phosphate layer is formed on the iron plating part so that a portion that was a conductive portion is blocked.

Further, in the needle contact of Comparative Example 2, the resistance value was unmeasurable (OL is 40 MΩ or higher), but in the planar contact, the resistance value was a value in the range of several KΩ to several MΩ. It is clear that there are countless conductive portions in the manganese phosphate layer (phosphating layer) to influence on the conductivity (insulating property) or the withstanding voltage. Accordingly, according to the measurement of planar contact, a conductivity that cannot be detected by the measurement of an electric resistance value using a needle type probe because a contact area with the target to be measured is too small so that a total amount of minute conduction parts is small may be detected. That is, in the measurement of the planar contact, a contact surface of the measurement block 74 is significantly larger than a leading end of the needle type probe, and a total amount of the minute conduction parts present in the range of the contact surface is significantly increased so that the conductivity is expressed through the measurement block 74. As a result, the electric resistance value of layers such as an insulation layer may be more precisely measured by this area effect and a level of the insulating property may be precisely confirmed by precisely determining whether there is a minute conduction part.

Further, in Examples 1 to 9, a withstanding voltage is improved as compared with Comparative Example 2. Further, with the increase in the number of layers, the withstanding voltage tends to further improve. It is considered that the withstanding voltage is improved because a portion corresponding to the conductive portion of the manganese phosphate layer is blocked. Further, it is considered that as the number of times of applying the second step and the third step is increased, that is, as the number of manganese phosphate layers is increased, the conductive portion of the manganese phosphate layer is blocked so that a total number of conductive portions is reduced to improve the withstanding voltage.

Further, in the evaluation of rust preventive property, when the number of manganese phosphate layers is 10, the rust is not observed even after 240 hours so that it is considered that there is barely any minute conduction part on the surface of the manganese phosphate layer. In this regard, it is considered that as the number of treatments of repeating the second step and the third step is increased, that is, as the number of manganese phosphate layers is increased, a total number of conductive portions of the manganese phosphate layer is reduced.

Further, in any of Examples, the insulation layer formed on the SPCC plate has a withstanding voltage performance of at least 250 V or higher. This is because when the above-described conductive layer 60 is used as an electric element and a lithium-ion secondary battery is used as a power supply connected to the conductive layer 60, a voltage of the lithium-ion secondary battery is 3.7 V so that the insulation layer has a withstanding voltage performance that is tens of times higher than a voltage of the power supply. Of course, a withstanding voltage performance is equal to or higher than the voltage of a primary battery such as a manganese battery, a nickel battery, or a lithium battery or a secondary battery such as a Ni—Cd battery or a nickel hydride storage battery.

Further, even though not represented in Tables, it is confirmed that even when a zinc phosphate layer or a zinc manganese phosphate layer is formed as an insulation layer instead of the manganese phosphate layer, as the number of layers (also understood as the number of treatments of repeating the second step and the third step) is increased, the withstanding voltage tends to improve.

Further, it is clear that in each Example, the resistance value significantly varies depending on the positions of the anode side probe and the cathode side probe. Specifically, as compared with the case that the anode side probe is in contact with a conductive portion having a good conductivity (a cathode side probe is in contact with the manganese phosphate layer), when the anode side probe is in contact with the manganese phosphate layer (a cathode side probe is in contact with a conductive portion having a good conductivity), the resistance value is significantly increased. In this regard, it is considered that a member having the insulation layer of the present disclosure in which a phosphating layer is formed on the base material has a rectifying action that makes it easy to flow the current from the base material, which is metal, to the phosphating layer, which is an insulation layer.

Accordingly, a member in which the phosphating layer 20 is formed on the base material 10 by utilizing a rectifying action may be used as a rectifier. That is, the rectifier is formed by junction of the base material 10, which is metal, and the phosphating layer 20 to simultaneously directly or indirectly install a terminal in the base material 10 and directly and indirectly install a terminal in the phosphating layer 20. Further, a direction of applying a voltage to the rectifier is not specifically limited and a terminal installed in the base material 10 may serve as an anode or may serve as a cathode.

Further, a conductive fluid used to measure the insulating property is not limited to water having a conductivity, and for example, may be a salt water, silver paste, or ion liquid, but may preferably select a conductive fluid that does not cause reaction, such as oxidation or dissolving, to the base material (SPCC plate).

Further, even though a size of the measurement block 74 used for the planar contact is not specifically limited, as illustrated in FIG. 11B, the bottom 76 may have a reduced size such that an area of a surface facing the manganese phosphate layer of the bottom 76 is smaller than the area of the bottom 76 of FIG. 11A. Specifically, when the bottom 76 has a reduced size, a gap between the measurement block 74 and the manganese phosphate layer may be easily buried with the conductive fluid. Further, it is desirable to configure such that the insulation treatment is applied to the planar type contact, that is, a side surface of the measurement block 74 and even though a conductive fluid that is interposed between the measurement block 74 and a surface of the manganese phosphate layer that is a portion to be measured protrudes between the measurement block 74 and the manganese phosphate layer to be in contact with the side surface of the measurement block 74, they do not conduct each other.

### EXPLANATION OF REFERENCE NUMERALS AND SYMBOLS

10: Base material
15: Metal plating part
20, 45: Phosphating layer
22: Conductive portion
30: Iron plating part
40: Second phosphating layer
42: Metal oxide
50: Insulation layer
60: Conductive layer

1. An insulation layer formation method, comprising:
a first step in which a surface treatment is applied to a base material to form thereon a high-resistance layer having high electric resistivity;
a second step in which metal plating parts are formed on the base material that has undergone the first step in such a manner as to allow a high-resistance layer to be formed thereon; and
a third step in which a high-resistance layer is formed on the base material that has undergone the second step.

2. The insulation layer formation method of claim 1, wherein the second step is a process of forming metal plating on a minute conduction part of the high-resistance layer formed by the first step.

3. The insulation layer formation method of claim 1, wherein the high-resistance layer is a phosphating layer formed by a phosphate chemical conversion treatment and the metal plating parts have metal to which the phosphate chemical conversion treatment is applicable and/or an oxidation treatment is applicable as a main component.

4. The insulation layer formation method of claim 3, wherein the high-resistance layer of the third step is formed by a phosphate chemical conversion treatment and/or an oxidation treatment.

5. An insulation layer formation method that forms an insulation layer having a high electric insulating property on a base material on which a high-resistance layer is not able to be directly formed, the method comprising:
a pre-process in which metal plating parts are formed on the base material as layers;
a first step in which a surface treatment is applied to form the high-resistance layer having high electric resistivity on the metal plating parts;
a second step in which metal plating parts are formed on the base material that has undergone the first step in such a manner as to allow the high-resistance layer to be formed thereon; and
a third step in which the high-resistance layer is formed on the metal plating parts formed in the second step by applying a treatment for forming the high-resistance layer to the base material that has undergone the second step.

6. The insulation layer formation method of claim 5, wherein the high-resistance layer is a phosphating layer formed by a phosphate chemical conversion treatment and the metal plating parts have metal to which the phosphate chemical conversion treatment is applicable and/or an oxidation treatment is applicable as a main component.

7. The insulation layer formation method of claim 5, wherein the high-resistance layer of the third step is formed by a phosphate chemical conversion treatment and/or an oxidation treatment.

8. The insulation layer formation method of claim 1, wherein the second step and the third step are alternately repeated.

9. The insulation layer formation method of claim 1, wherein in the second step, the metal plating parts are formed by wet plating.

10. The insulation layer formation method of claim 1, wherein the metal plating parts have iron, tin, zinc, or nickel as a main component.

11. The insulation layer formation method of claim 5, further comprising:
a formation step in which a conductive layer is formed on an upper layer of the high-resistance layer, which is an outermost surface.

12. The insulation layer formation method of claim 11, wherein the conductive layer is formed with a planar shape, a linear shape, a mesh shape, a geometric shape and/or a dot shape, or a configuration formed by a combination thereof.

13. The insulation layer formation method of claim 11, wherein the conductive layer forms a conductive pattern.

14. The insulation layer formation method of claim 11, wherein a width, a thickness, and a direction installed on the high-resistance layer of the conductive layer are set so as to form an electric element.

15. A member with an insulation layer, wherein a phosphating layer is formed on a surface of a base material, a conductive liquid is applied on a surface of the phosphating layer, an anode side probe is brought into contact with a conductive portion and a cathode side probe is brought into contact with the phosphating layer so that a resistance value measured by a planar type probe of approximately 78 mm² is 190 KΩ or higher.

16. The member of claim 15, wherein the insulation layer is configured by a substantially uniform phosphating layer on a surface of a base material.

17. The member of claim 15, wherein the insulation layer is a planar insulation layer in which everywhere of the entire surface where the insulation layer is formed is insulated.

18. The member of claim 15, wherein the insulation layer is mainly configured by a phosphating layer on a surface of a base material and metal oxides are scattered on the insulation layer.

19. The member of claim 15, wherein a conductive layer is formed on an upper layer of the insulation layer.

20. The member of claim 19, wherein the conductive layer is formed with a planar shape, a linear shape, a mesh shape, a geometric shape and/or a dot shape, or a configuration formed by a combination thereof.

21.-32. (canceled)
